(19) United States
(12) Patent Application Publication
(10) Pub. No.: US 2024/0128248 A1
(43) Pub. Date: Apr. 18, 2024

(54) SEMICONDUCTOR DEVICE

(71) Applicant: RENESAS ELECTRONICS CORPORATION, Tokyo (JP)

(72) Inventors: Yasutaka NAKASHIBA, Tokyo (JP); Hiroshi MIYAKI, Tokyo (JP); Takayuki IGARASHI, Tokyo (JP)

(21) Appl. No.: 18/365,455

(22) Filed: Aug. 4, 2023

(30) Foreign Application Priority Data
Oct. 12, 2022 (JP) 2022-163944

(51) Int. Cl. H01L 25/16; H01F 27/28; H01F 27/30; H01L 23/00

(52) U.S. Cl. CPC H01L 25/16; H01F 27/2804; H01F 27/306; H01L 24/32; H01F 27/324; H01L 24/33; H01L 24/48; H01L 24/73; H01L 2224/32245; H01L 2224/32265; H01L 2224/3303; H01L 2224/33181; H01L 2224/48091; H01L 2224/48265; H01L 2224/73265; H01L 2924/19042; H01L 2924/19104

(57) ABSTRACT

A semiconductor device includes an insulating substrate and an upper inductor that is formed on the insulating substrate and is a component of a transformer that performs contactless communication between different potentials. Here, the upper inductor is configured to be applied with a first potential. The upper inductor is formed so as to be magnetically coupled to a lower inductor that is configured to be applied with a second potential different from the first potential.

### CROSS-REFERENCE TO RELATED APPLICATIONS

The disclosure of Japanese Patent Application No. 2022-163944 filed on Oct. 12, 2022, including the specification, drawings and abstract is incorporated herein by reference in its entirety.

### BACKGROUND

The present disclosure relates to a semiconductor device and, more particularly, to a technique applicable to a semiconductor device capable of transmitting signals between different potentials using a pair of inductors coupled inductively.

There are disclosed techniques listed below.
[Patent Document 1] Japanese Unexamined Patent Application Publication No. 2011-082212

Patent Document 1 discloses a technique capable of increasing cross-sectional areas of coils without preventing miniaturization in order to reduce a series resistance which occupies most of the parasitic resistance components of the coils configuring the transformer.

### SUMMARY

For example, a transformer (digital isolator) that enables contactless signal transmission using a pair of inductors coupled inductively is known. Since this transformer allows signal transmission in a contactless state, the electrical noise from one circuit can be suppressed from adversely affecting the other circuit. In addition, in the transformer configured as described above, improving the breakdown voltage so as to enable contactless signal transmission between circuits having different potentials from each other.

In one embodiment, a semiconductor device includes an insulating substrate, and a first inductor formed on the insulating substrate and being a component of a transformer that performs contactless communication between different potentials. Here, the first inductor is configured to be applied with a first potential. The first inductor is formed so that the first inductor can be magnetically coupled with a second inductor configured to be applied with a second potential different from the first potential.

According to one embodiment, the reliability of the semiconductor device can be improved.

### BRIEF DESCRIPTION OF THE DRAWINGS

FIG. 1 is a diagram showing a configuration example of a drive control unit that drives a load circuit such as a motor.

FIG. 2 is an explanatory diagram showing a signal transmission example.

FIG. 3 is a diagram showing a two-chip configuration.

FIG. 4 is a cross-sectional view showing a configuration of a semiconductor device according to first embodiment.

FIG. 5 is a cross-sectional view showing a detailed insulating structure.

FIG. 6 is a chart comparing the characteristics of glass substrate and resin substrate.

FIG. 7 is a cross-sectional view showing a manufacturing step of the insulating structure.

FIG. 8 is a cross-sectional view showing a manufacturing step of the insulating structure subsequent to FIG. 7.

FIG. 9 is a cross-sectional view showing a manufacturing step of the insulating structure subsequent to FIG. 8.

FIG. 10 is a cross-sectional view showing a manufacturing step of the insulating structure subsequent to FIG. 9.

FIG. 11 is a cross-sectional view showing a manufacturing step of the insulating structure subsequent to FIG. 10.

FIG. 12 is a diagram showing a three-chip configuration.

FIG. 13 is a cross-sectional view showing a configuration of a semiconductor device according to a first modified example of the first embodiment.

FIG. 14 is a cross-sectional view showing a configuration of a semiconductor device according to a second modified example of the first embodiment.

FIG. 15 is a cross-sectional view showing a configuration of a semiconductor device according to a second embodiment.

FIG. 16A is an upper surface diagram of an insulating structure having a transformer, and FIG. 16B is a cross-sectional view along A-A line in FIG. 16A.

FIG. 17 is a cross-sectional view showing a manufacturing step of the insulating structure.

FIG. 18 is a cross-sectional view showing a manufacturing step of the insulating structure subsequent to FIG. 17.

FIG. 19 is a cross-sectional view showing a manufacturing step of the insulating structure subsequent to FIG. 18.

FIG. 20 is a cross-sectional view showing a manufacturing step of the insulating structure subsequent to FIG. 19.

FIG. 21A is an upper surface diagram showing a configuration of an insulating structure according to a first modified example of the second embodiment, FIG. 21B is a cross-sectional view along A-A line in FIG. 21A, and FIG. 21C is a bottom view showing the configuration of the insulating structure according to the first modified example of the second embodiment.

FIG. 22 is an upper surface diagram showing a configuration of an insulating structure according to a second modified example of the second embodiment.

### DETAILED DESCRIPTION

In all the drawings for explaining the embodiments, the same members are denoted by the same reference numerals in principle, and repetitive descriptions thereof are omitted. Note that even plan view may be hatched for the sake of clarity. CIRCUIT CONFIGURATION

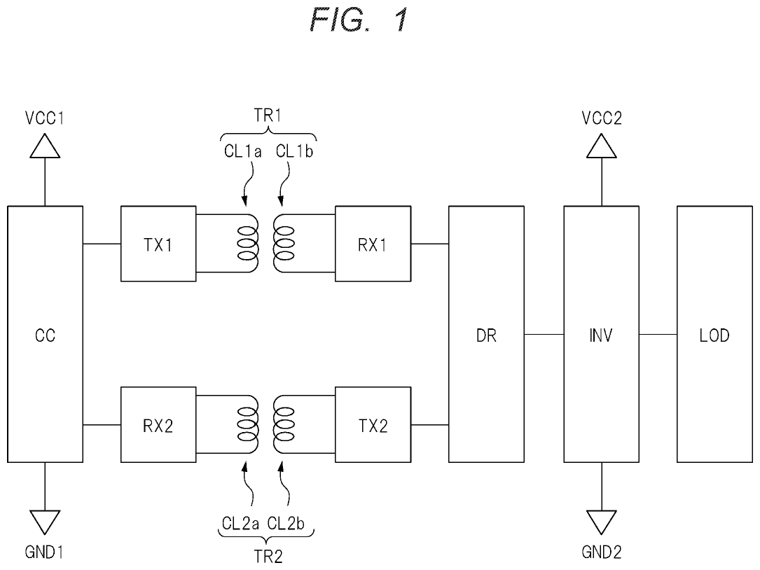

FIG. 1 is a diagram showing a configuration example of a drive control unit that drives the load circuit such as a motor.

As shown in FIG. 1, the drive control unit includes a control circuit CC, a transformer TR1, a transformer TR2, the drive circuit DR, and an inverter INV, and is electrically connected to a load circuit LOD.

A transmitting circuit TX1 and a receiving circuit RX1 transmits a control signal outputted from the control circuit CC to the drive circuit DR. On the other hand, a transmitting circuit TX2 and a receiving circuit RX2 transmits a signal outputted from the drive circuit DR to the control circuit CC.

The control circuit CC has a function of controlling the drive circuit DR. The drive circuit DR operates the inverter INV that controls the load circuit LOD, based on control from the control circuit CC.

The control circuit CC is supplied with a power supply potential VCC1, and the control circuit CC is grounded by the ground potential GND1. On the other hand, the inverter INV is supplied with a power supply potential VCC2, and the inverter INV is grounded by the ground potential GND2. In this case, for example, the power supply potential VCC1 is smaller than the power supply potential VCC2 supplied to the inverter INV. In other words, the power supply potential VCC2 supplied to the inverter INV is greater than the power supply potential VCC1.

The transformer TR1 formed of a coil CL1a and a coil CL1b inductively (magnetically) coupled to each other is interposed between the transmitting circuit TX1 and the receiving circuit RX1. Thus, a signal can be transmitted from the transmitting circuit TX1 to the receiving circuit RX1 via the transformer TR1. Consequently, the drive circuit DR can receive the control signal outputted from the control circuit CC via the transformer TR1.

As described above, the transformer TR1 electrically isolated using the inductive coupling enables transmitting the control signal from the control circuit CC to the drive circuit DR while suppressing the transfer of the electric noise from the control circuit CC to the drive circuit DR. Therefore, a malfunction of the drive circuit DR caused by the superimposition of the electric noise on the control signal can be suppresses. Thus, the operation reliability of the semiconductor device can be improved.

The coil CL1a and the coil CL1b configuring the transformer TR1 each function as an inductor. The transformer TR1 function as a magnetically coupled element formed of the coil CL1a and the coil CL1b inductively coupled to each other.

Similarly, the transformer TR2 formed of a coil CL2b and a coil CL2a inductively coupled to each other is interposed between the transmitting circuit TX2 and the receiving circuit RX2. Thus, a signal can be transmitted from the transmitting circuit TX2 to the receiving circuit RX2 via the transformer TR2. Consequently, the control circuit CC can receive the signal outputted from the drive circuit DR via the transformer TR2.

As described above, the transformer TR2 electrically isolated using the inductive coupling enables transmitting the signal from the drive circuit DR to the control circuit CC while suppressing the transfer of the electric noise from the drive circuit DR to the control circuit CC. Therefore, a malfunction of the control circuit CC caused by the superimposition of the electric noise on the signal can be suppresses. Thus, the operation reliability of the semiconductor device can be improved.

The transformer TR1 is configured by the coil CL1a and the coil CL1b, and the coil CL1a and the coil CL1b are not connected by conductors but are magnetically coupled. Therefore, when a current flows in the coil CL1a, an induced electromotive force is generated in the coil CL1b in accordance with a change in the current, so that an induced current flows in the coil CL1b. In this case, the coil CL1a is a primary coil, and the coil CL1b is a secondary coil. As described above, the transformer TR1 utilizes the electromagnetic induction phenomenon occurring between the coil CL1a and the coil CL1b. That is, as a result of transmitting a signal from the transmitting circuit TX1 to the coil CL1a of the transformer TR1 to flow a current, the receiving circuit RX1 detects an induced current generated in the coil CL1b of the transformer TR1, so that the receiving circuit RX1 can receive a signal corresponding to the control signal outputted from the transmitting circuit TX1.

Similarly, the transformer TR2 is configured by the coil CL2a and the coil CL2b, and the coil CL2a and the coil CL2b are not connected by conductors but are magnetically coupled. Therefore, when a current flows in the coil CL2b, an induced electromotive force is generated in the coil CL2a in accordance with a change in the current, so that an induced current flows in the coil CL2a. As described above, as a result of transmitting a signal from the transmitting circuit TX2 to the coil CL2b of the transformer TR2 to flow a current, the receiving circuit RX2 detects an induced current generated in the coil CL2a of the transformer TR2, so that the receiving circuit RX2 can receive a signal corresponding to the control signal outputted from the transmitting circuit TX2.

A signal transmission is performed between the control circuit CC and the drive circuit DR using a path from the transmitting circuit TX1 to the receiving circuit RX1 via the transformer TR1 and using a path from the transmitting circuit TX2 to the receiving circuit RX2 via the transformer TR2. That is, the signal transmission can be performed between the control circuit CC and the drive circuit DR by the receiving circuit RX1 receiving the signal transmitted by the transmitting circuit TX1 and by the receiving circuit RX2 receiving the signal transmitted by the transmitting circuit TX2. As described above, the transformer TR1 is interposed in the signal transmission from the transmitting circuit TX1 to the receiving circuit RX1, and the transformer TR2 is interposed in the signal transmission from the transmitting circuit TX2 to the receiving circuit RX2. Thus, the drive circuit DR can drive the inverter INV operating the load circuit LOD in accordance with the signal transmitted from the control circuit CC.

The control circuit CC and the drive circuit DR have different reference potentials. That is, the reference potential is fixed to the ground potential GND1 in the control circuit CC, while the drive circuit DR is electrically connected to the inverter INV as shown in FIG. 1.

The inverter INV includes, for example, a high-side IGBT (Insulated Gate Bipolar Transistor) and a low-side IGBT. The drive circuit DR performs the on/off control of the high-side IGBT and the on/off control of the low-side IGBT in the inverter INV resulting in that the inverter INV can control the load circuit LOD.

Specifically, the drive circuit DR performs the on/off control of the high-side IGBT by controlling the potential applied to the gate electrode of the high-side IGBT. Similarly, the drive circuit DR performs the on/off control of the low-side IGBT by controlling the potential applied to the gate electrode of the low-side IGBT.

Here, for example, the on-control of the low-side IGBT is realized by applying “emitter potential (0 V)+threshold voltage (15 V)” to the gate electrode with reference to the emitter potential (0V) of the low-side IGBT connected to the ground potential GND2.

On the other hand, for example, the off-control of the low-side IGBT is realized by applying an “emitter potential (0 V)” to the gate electrode with reference to the emitter potential (0 V) of the low-side IGBT connected to the ground potential GND2.

Therefore, the on/off control of the low-side IGBT is performed according to whether or not applying the threshold voltage (15 V) to the gate electrode with 0 V as a reference potential.

On the other hand, for example, the on-control of the high-side IGBT is performed by whether or not applying “reference potential+threshold voltage (15 V)” to the gate electrode with reference to the reference potential using the emitter potential of the high-side IGBT as a reference potential.

However, the emitter potential of the high-side IGBT is not fixed to the ground potential GND2 as is the emitter potential of the low-side IGBT. That is, the high-side IGBT and the low-side IGBT are connected in series between the power supply potential VCC2 and the ground potential GND2 in the inverter INV. In the inverter INV, when the high-side IGBT is set to on-state, the low-side IGBT is set to off-state, and when the high-side IGBT is set to off-state, the low-side IGBT is set to on-state.

Therefore, when the high-side IGBT is set to off-state, since the low-side IGBT is set to on-state, the emitter potential of the high-side IGBT becomes the ground potential GND2 due to the low-side IGBT set to on-state.

On the other hand, when the high-side IGBT is set to on-state, since the low-side IGBT is set to off-state, the emitter potential of the high-side IGBT becomes an IGBT bus voltage. In this case, the on/off control of the high-side IGBT is performed by whether or not applying “reference potential+threshold voltage (15V)” to the gate electrode with the emitter potential of the high-side IGBT as a reference potential.

As described above, the emitter potential of the high-side IGBT varies depending on whether the high-side IGBT is set to on-state or off-state. That is, the emitter potential of the high-side IGBT varies from the ground potential GND2 (0 V) to the power supply potential VCC2 (for example, 800 V). Therefore, in order to set the high-side IGBT to on-state, the “IGBT bus voltage (800 V)+threshold voltage (15 V)” needs to be applied to the gate electrode with the emitter potential of the high-side IGBT as a reference potential.

Therefore, the drive circuit DR that performs the on/off control of the high-side IGBT needs to detect the emitter potential of the high-side IGBT. Therefore, the drive circuit DR is configured to receive the emitter potential of the high-side IGBT. Consequently, the drive circuit DR receives the reference potential of 800 V, and the drive circuit DR controls to set the high-side IGBT to on-state by applying the threshold voltage of 15 V to the gate electrode of the high-side IGBT with respect to the reference potential of 800 V. Therefore, a high potential of the order of 800 V is applied to the drive circuit DR.

As described above, the drive control unit includes the control circuit CC that handles the low potential (several tens of volts) and the drive circuit DR that handles the high potential (several hundreds of volts). Therefore, the signal transmission between the control circuit CC and the drive circuit DR requires the signal transmission between the different potential circuits. In this regard, the signal transmission between the control circuit CC and the drive circuit DR is performed via the transformer TR1 and the transformer TR2, so that the signal can be transmitted between different potential circuits.

As described above, a large potential difference may be generated between the primary coil and the secondary coil in the transformer TR1 and the transformer TR2. Conversely, since a large potential difference may be generated, the primary coil and the secondary coil magnetically coupled to each other without being connected by a conductor are used for signal transmission. Therefore, in forming the transformer TR1, increasing the breakdown voltage between the coil CL1a and the coil CL1b as much as possible is required from the viewpoint of improving the operation reliability of the semiconductor device. Similarly, in forming the transformer TR2, increasing the breakdown voltage between the coil CL2b and the coil CL2a as much as possible is required from the viewpoint of improving the operation reliability of the semiconductor device.

### Signal Transmission Example

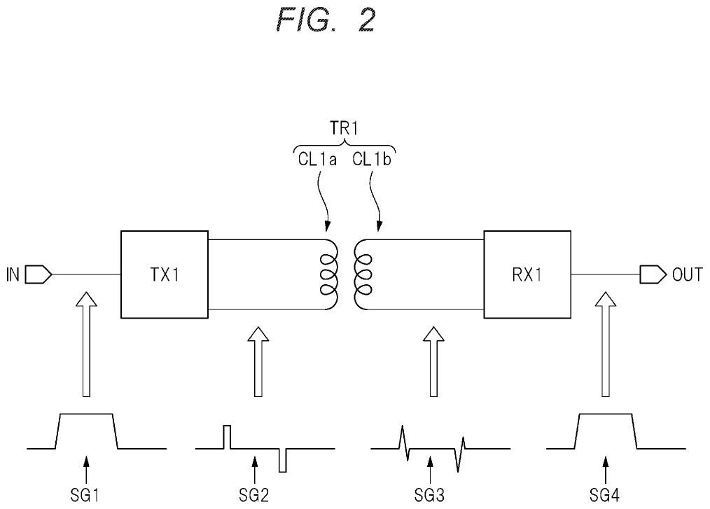

FIG. 2 is an explanatory diagram showing the signal transmission example.

In FIG. 2, the transmitting circuit TX1 extracts an edge part of a signal SG1 of the square wave inputted to the transmitting circuit TX1, generates a signal SG2 having a constant pulse width, and transmits the signal SG2 to the coil CL1a (primary coil) of the transformer TR1. When the current caused by the signal SG2 flows to the coil CL1a of the transformer TR1 (primary coil), a signal SG3 flows to the coil CL1b (secondary coil) of the transformer TR1 by the induced electromotive force. The receiving circuit RX1 amplifies the signal SG3 and further modulates into a square wave, and then the receiving circuit RX1 outputs a signal SG4 of the square wave. Thus, the receiving circuit RX1 can output the signal SG4 corresponding to the signal SG1 inputted to the transmitting circuit TX1. In this way, the signal can be transmitted from the transmitting circuit TX1 to the receiving circuit RX1. Similarly, the signal transmission can be transmitted from the transmitting circuit TX2 to the receiving circuit RX2.

### Two-Chip Configuration

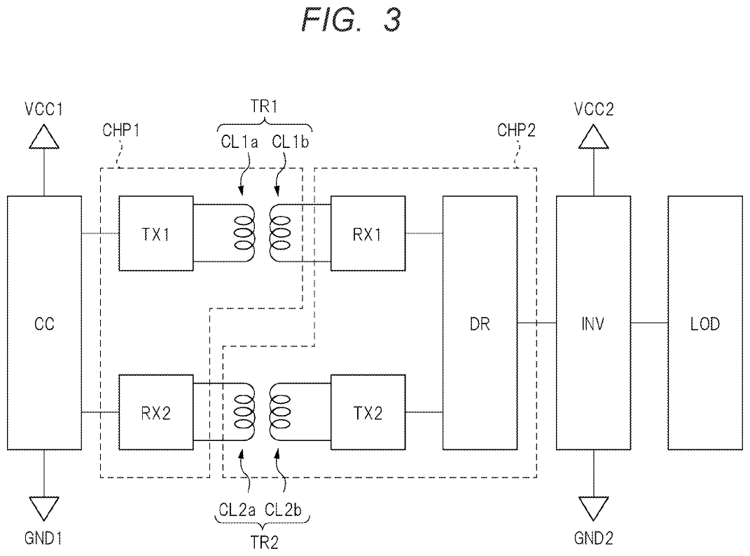

The transceiver circuit portion of the drive control unit described above, for example, is formed separately into two semiconductor chips. Specifically, FIG. 3 is a diagram showing the two-chip configuration. In FIG. 3, the transmitting circuit TX1, the transformer TR1, and the receiving circuit RX2 are formed in a semiconductor chip CHP1. On the other hand, the receiving circuit RX1, the drive circuit DR, the transmitting circuit TX2, and the transformer TR2 are formed in a semiconductor chip CHP2.

In such a two-chip configuration, for example, the transformer TR1 is formed on the same semiconductor chip CHP1 as the transmitting circuit TX1 and the receiving circuit RX2. Therefore, the transformer TR1, the transmitting circuit TX1, and the receiving circuit RX2 can be integrated. Similarly, the transformer TR2 is formed on the same semiconductor chip CHP2 as the drive circuit DR, the receiving circuit RX1, and the transmitting circuit TX2. Therefore, the transformer TR2, the drive circuit DR, the receiving circuit RX1, and the transmitting circuit TX2 can be integrated.

Here, for example, since the transmitting circuit TX1 and the receiving circuit RX2 are formed in the semiconductor chip CHP1, transistors configuring the transmitting circuit TX1 and the receiving circuit RX2 are formed in the semiconductor chip CHP1. Similarly, since the drive circuit DR, the receiving circuit RX1, and the transmitting circuit TX2 are formed in the semiconductor chip CHP2, transistors configuring the drive circuit DR, the receiving circuit RX1, and the transmitting circuit TX2 are also formed in the semiconductor chip CHP2. Therefore, in the semiconductor chip CHP1, the transformer TR1 and the transistors are formed together. Similarly, in the semiconductor chip CHP2, the transformer TR2 and the transistors are formed together.

### Consideration for Improvement

As described above, in the two-chip configuration, since the transformer and the transistors are formed on one semiconductor chip, the transformer is formed by using the normal CMOS technique for the transistor.

Specifically, in the normal CMOS technique, a transistor is formed on a semiconductor substrate, and a plurality of wiring layers is formed over the transistor. Here, in the normal CMOS technique, a lower layer wiring formed in a lower wiring layer connects transistors next to each other, and has a short connecting length. Therefore, since the parasitic resistance does not need to be considered as much in the lower layer wiring, the lower layer wiring is configured by a local wiring having a narrow width and a small wiring thickness.

On the other hand, in the normal CMOS technique, an upper layer wiring formed in an upper wiring layer connects circuits separated from each other by a distance, and the connecting length of the upper layer wiring becomes long. Consequently, in the upper layer wiring, the parasitic resistance must be considered and configured by a global wiring having a large width and a large wiring thickness. As described above, in the plurality of wiring layers in the normal CMOS technique, a fine local wiring is formed in the lower wiring layer. In the layers above the lower wiring layer, the closer the layer is disposed to the upper wiring layer, the greater the wiring width and the wiring thickness of the wiring formed in the layer will be. That is, in the normal CMOS technique, the wirings formed in the plurality of wiring layers are configured by a local wiring formed in the lower wiring layer, a semi-global wiring formed in the middle wiring layer, and a global wiring formed in the upper wiring layer.

When the transformer is formed on the premise of such a normal CMOS technique, the lower inductor, which is a component of the transformer, is formed using a local wiring formed in the lower wiring layer. On the other hand, the upper inductor, which is a component of the transformer, is formed using a global wiring formed in the upper wiring layer. As a result, an enough distance can be secured between the lower inductor and the upper inductor (the distance in the thickness direction of the semiconductor chip), so that the breakdown voltage of the transformer can be secured.

However, in recent years, it has been desired to further improve the breakdown voltage of the transformer, and a technique for improving the breakdown voltage of the transformer is required.

For example, in the normal CMOS technique, transistors are formed on the semiconductor substrate, and a multilayer wiring layer is formed over the semiconductor substrate in which the transistors are formed. In this case, the thickness of the semiconductor substrate is about 400 μm, while the thickness of the multilayer wiring layer is about 4 μm.

Therefore, when the transformer is formed in the multilayer wiring layer using the normal CMOS technique, a distance between the lower inductor and the upper inductor configuring the transformer is at most about 4 μm. However, when the distance between the lower inductor and the upper inductor is about 4 μm, it is difficult to secure the enough breakdown voltage (galvanic breakdown voltage) between the lower inductor and the upper inductor.

Therefore, on the premise that the normal CMOS technique is used, an attempt has been made to secure a distance between the lower inductor and the upper inductor by increasing the thickness of the multilayer wiring layer. However, when the normal CMOS technique is used, the thickness of the multilayer wiring layer cannot be increased to any extent due to factors such as “warpage” in the semiconductor substrate, and for example, the thickness is limited to set the multilayer wiring layer to about 20 μm. That is, when the normal CMOS technique is employed, the distance between the lower inductor and the upper inductor are limited to about 20 μm.

In this regard, since the breakdown voltage required for the transformer is 3750 V in terms of alternating current (in AC), the breakdown voltage can be ensured by devising even when the transformer is formed using a normal CMOS technique.

However, in order to improve the transmission efficiency, it is desirable to use a high voltage, and therefore, the breakdown voltage required for the transformer is further increased in the future. Specifically, the breakdown voltage required for the transformer is 5000 V in terms of alternating current (AC).

Therefore, the distance between the lower inductor and the upper inductor must be about 100 μm or more, which cannot be dealt with by a technique of forming a transformer using a normal CMOS technique. In other words, in order to realize the transformer having the breakdown voltage of about 5000 V in terms of alternating current, a new designing concept different from the normal CMOS technique is required.

Therefore, in the following, in order to realize the transformer having the breakdown voltage of about 5000 V in terms of alternating current, a technical idea developed based on a new designing concept that is different from the normal CMOS technique will be described.

### Basic Concept

The basic concept is that the breakdown voltage of the transformer is ensured using a new insulating substrate different from the semiconductor substrate in which the multilayer wiring layer is formed, instead of securing the breakdown voltage of the transformer using the thickness of the multilayer wiring layer (thickness of the laminated insulating films). In other words, the basic concept is that a new insulating substrate is prepared to secure the distance between the lower inductor and the upper inductor by, for example, the thickness of the insulating substrate.

According to this basic concept, by setting the thickness of the insulating substrate to about 100 μm, it is possible to set the distance between the lower inductor and the upper inductor to about 100 μm, so that it is possible to realize a transformer having a breakdown voltage of about 5000V in terms of alternating current.

In the following, an embodiment embodying the basic concept will be described.

### First Embodiment

### Configuration of Semiconductor Device

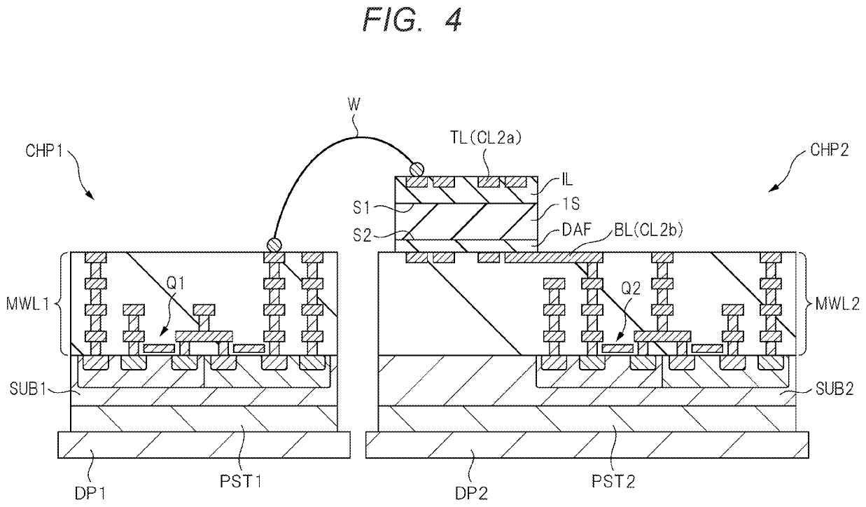

FIG. 4 is a cross-sectional view showing a schematic configuration of a semiconductor device in the first embodiment.

In FIG. 4, the semiconductor device includes the semiconductor chip CHP1 and the semiconductor chip CHP2. The semiconductor chip CHP1 is mounted, for example, on the die pad DP1 that is a chip mounting portion via a conductive adhesive PST1. On the other hand, the semiconductor chip CHP2 is mounted, for example, on the die pad DP2 which is a chip mounting portion via a conductive adhesive PST2. Here, each of the die pad DP1 and the die pad DP2 is made of, for example, a copper material. Each of the conductive adhesive PST1 and the conductive adhesive PST2 is made of, for example, silver-paste or solder.

The transmitting circuit TX1 and the receiving circuit RX2 shown in FIG. 3 are formed in the semiconductor chip CHP1. As shown in FIG. 4, the semiconductor chip CHP1 includes a semiconductor substrate SUB1 and a multilayer wiring layer MWL1 formed on the semiconductor substrate SUB1. A plurality of transistors Q1 is formed on the semiconductor substrate SUB1, and the multilayer wiring layer MWL1 is formed over the semiconductor substrate SUB1 in which the plurality of transistors Q1 is formed. In the multilayer wiring layer MWL1, a plurality of interlayer insulating films and a plurality of wirings are laminated. A wiring is formed in each layer of the multilayer wiring layer MWL1, and the wiring is electrically connected to the transistor Q1. The transistor Q1 and the wiring electrically connected to each other configure the transmitting circuit TX1 and the receiving circuit RX2.

The thickness of the semiconductor substrate SUB1 is about 400 μm, and the thickness of the multilayer wiring layer MWL1 is about 4 μm. Therefore, the semiconductor chip CHP1 has a thickness of about 404 μm.

Next, the drive circuit DR, the receiving circuit RX1, and the transmitting circuit TX2 shown in FIG. 3 are formed in the semiconductor chip CHP2. As shown in FIG. 4, the semiconductor chip CHP2 includes a semiconductor substrate SUB2 and a multilayer wiring layer MWL2 formed on the semiconductor substrate SUB2. A plurality of transistors Q2 is formed in the semiconductor substrate SUB2, and the multilayer wiring layer MWL2 is formed over the semiconductor substrate SUB2 in which the plurality of transistors Q2 is formed. In the multilayer wiring layer MWL2, a plurality of interlayer insulating films and a plurality of wiring are laminated. A wiring is formed in each layer of the multilayer wiring layer MWL2, and the wiring is electrically connected to the transistor Q2. The transistor Q2 and the wiring electrically connected to each other configure the drive circuit DR, the receiving circuit RX1, and the transmitting circuit TX2. In addition to the wiring, the multilayer wiring layer MWL2 is also formed with a lower inductor BL (coil CL2b) that is a component of the transformer. The lower inductor BL is formed of, for example, a spiral wiring.

Subsequently, as shown in FIG. 4, in the semiconductor chip CHP2, an insulating substrate 1S is laminated on the multilayer wiring layer MWL2 via an adhesive member DAF. Here, the adhesive member DAF is formed of, for example, a die attach film. The insulating substrate 1S is made of a glass substrate. On the insulating substrate 1S, an insulating layer IL and an upper inductor TL (coil CL2a) which is formed on the insulating layer IL and is a component of the transformer are formed. The upper inductor TL is electrically connected to, for example, the wiring disposed in the multilayer wiring layer MWL1 of the semiconductor chip CHP1 via a bonding wire W. The upper inductor TL is formed of, for example, a spiral wiring.

The thickness of the insulating substrate 1S is greater than the thickness of the multilayer wiring layer MWL1. Specifically, the thickness of the semiconductor substrate SUB2 is about 400 μm, the thickness of the multilayer wiring layer MWL2 is about 4 μm, and the thickness of the insulating substrate 1S is about 100 μm. As described above, the insulating substrate 1S having a thickness of about 100 μm is laminated on the semiconductor chip CHP2 having a thickness of about 404 μm.

Further, the configuration of the semiconductor device in the first embodiment will be described.

In the first embodiment, the semiconductor device includes the insulating substrate 1S and the upper inductor TL formed on the insulating substrate 1S and being a component of a transformer that performs contactless communication between different potentials. In this case, the upper inductor TL is electrically connected to wiring present in the multilayer wiring layer MWL1 formed in the semiconductor chip CHP1 and is applied with the first potential. Specifically, the semiconductor device includes the semiconductor chip CHP1 including a circuit (first circuit) that applies the first potential to the upper inductor TL. The upper inductor TL formed on the insulating substrate 1S is electrically connected to a circuit formed in the semiconductor chip CHP1 via the bonding wire W that is an exemplary conductive member. Accordingly, the first potential outputted from the circuit formed in the semiconductor chip CHP1 is applied to the upper inductor TL.

The semiconductor device includes the semiconductor chip CHP2 having the lower inductor BL, and the semiconductor chip CHP2 includes a circuit (second circuit) applying a second potential to the lower inductor BL. Accordingly, the second potential outputted from the circuit formed in the semiconductor chip CHP2 is applied to the lower inductor BL. Consequently, the first potential is applied to the upper inductor TL, while the second potential is applied to the lower inductor BL.

Here, the upper inductor TL is formed so as to be magnetically coupled to the lower inductor BL to which the second potential different from the first potential is applied in the thickness direction of the insulating substrate 1S. Specifically, the insulating substrate 1S has a first surface S1 and a second surface S2 located opposite the first surface S1. The insulating substrate 1S is laminated on the semiconductor chip CHP2 via the adhesive member DAF such that the lower inductor BL faces the second surface S2 while the upper inductor TL is formed on the first surface S1. Thus, the upper inductor TL and the lower inductor BL are configured to be magnetically coupled to each other.

The semiconductor chip CHP2 includes the transistor Q2 formed on the semiconductor substrate SUB2 and the multilayer wiring layer MWL2 formed over the transistor Q2, and the lower inductor BL is formed in the multilayer wiring layer MWL2. For example, the lower inductor BL is formed in the uppermost layer of the multilayer wiring layer MWL2. However, the lower inductor BL may not be disposed in the uppermost layer of the multilayer wiring layer MWL2. For example, when the multilayer wiring layer MWL2 is formed using the normal CMOS technique and the multilayer wiring layer MWL2 includes a local wiring, a semi-global wiring, and a global wiring, the lower inductor BL can be formed in the same wiring layer as either the semi-global wiring or the global wiring.

The semiconductor device in the first embodiment is configured as described above.

### Features of Semiconductor Device

A first feature point of the semiconductor device according to the first embodiment is that, for example, as shown in FIG. 4, the insulating substrate 1S is disposed on the semiconductor chip CHP2 such that the insulating substrate 1S having the upper inductor TL is disposed to face the lower inductor BL formed on the semiconductor chip CHP2 in the thickness direction of the insulating substrate 1S.

Thus, according to the semiconductor device of the first embodiment, the breakdown voltage between the upper inductor TL and the lower inductor BL can be ensured by the thickness of the insulating substrate 1S while the upper inductor TL and the lower inductor BL are magnetically coupled to form the transformer. For example, by setting the thickness of the insulating substrate to about 100 μm, the insulating distance between the lower inductor BL and the upper inductor TL can be set to about 100 μm, so that a transformer having a breakdown voltage of about 5000 V in alternating current can be realized.

As described above, in the first feature, the breakdown voltage of the transformer is secured by using a new insulating substrate 1S different from the semiconductor chip CHP2 on which the multilayer wiring layer MWL2 is formed, rather than securing the breakdown voltage of the transformer by the thickness of the multilayer wiring layer MWL2 formed on the semiconductor chip CHP2. That is, in the first feature, the insulating distance between the lower inductor BL and the upper inductor TL is ensured by the thickness of the insulating substrate 1S different from the semiconductor chip CHP2, instead of securing the insulating distance between the upper inductor TL and the lower inductor BL by the multilayer wiring layer MWL2 in the semiconductor chip CHP2 formed using the normal CMOS technique. Thus, according to the first feature, it is possible to secure the breakdown voltage of the transformer that is difficult to realize by using the normal CMOS technique. Thus, according to the first feature, a higher breakdown voltage can be ensured, and thus the reliability of the semiconductor device can be improved.

Furthermore, for example, if a normal CMOS technique is used to ensure the insulating distance between the lower inductor BL and the upper inductor TL, a maximum of 20 μm is a limitation. Therefore, it is difficult to realize a transformer having a breakdown voltage of about 5000 V in alternating current in a technique of forming a transformer using the normal CMOS technique.

On the other hand, according to the first feature, the breakdown voltage of the transformer can be easily secured by adjusting the thickness of the insulating substrate 1S different from the semiconductor chip CHP2 using the normal CMOS technique. For example, by using the insulating substrate 1S, an insulating distance of about 100 μm, which is difficult to realize by the normal CMOS technique, can be easily realized.

Further, by adjusting the thickness of the insulating substrate 1S, it is also easy to design the breakdown voltage of the transformer to a predetermined value. That is, the first feature point has a great technical significance in that it is possible not only to realize a transformer having a breakdown voltage of 5000 V in terms of alternating current but also to provide a design method that facilitates designing the breakdown voltage of the transformer to various values by appropriately adjusting the thickness of the insulating substrate 1S. For example, further increasing the thickness of the insulating substrate 1S can realize a larger breakdown voltage of the transformer. In addition, depending on the required specifications of the transformer, a small breakdown voltage of the transformer can be realized by reducing the thickness of the insulating substrate 1S.

Subsequently, a second feature point of the semiconductor device according to the first embodiment is that, for example, the lower inductor BL formed in the semiconductor chip CHP2 is disposed in the same wiring layer as wiring layer formed with one of the semi-global wiring and the global wiring in the multilayer wiring layer MWL2. In other words, the second feature is that the lower inductor BL is formed in the same layer as the semi-global wiring or the global wiring formed by the normal CMOS technique.

Thus, according to the second feature, the thickness of the lower inductor BL can be made equal to the thickness of the semi-global wiring or the thickness of the global wiring. Since the thickness of the semi-global wiring and the thickness of the global wiring are greater than the thickness of the local wiring, so that the parasitic resistance of the lower inductor BL can be reduced. Therefore, according to the second feature point, it is possible to suppress the deterioration of the signal amplitude of the signal that transmits in the lower inductor BL.

For example, in the normal CMOS technique, the lower layer wiring is configured by the local wiring, while the upper layer wiring is configured by the global wiring. The designing concept such a normal CMOS technique is based on that the lower layer wiring is a wiring connecting adjacent transistors and the parasitic resistance of wiring may not be considered as much while the upper layer wiring is a wiring connecting circuits separated from each other and the parasitic resistance of wiring needs to be considered.

In this regard, in a technique of forming a transformer by using a normal CMOS technique, the lower inductor is formed in a wiring layer that is the same layer as a wiring layer in which a local wiring is disposed. However, since a large current flows through the lower inductor, the influence of the parasitic resistance is large. Specifically, when the lower inductor is formed in wiring layer in the same layer as wiring layer in which the local wiring is disposed, the lower inductor has a high resistance, and consequently, the signal amplitude of the signal that transmits in the lower inductor deteriorates due to the high-resistance parasitic resistance. This is because the local wiring is designed based on the designing concept of the normal CMOS technique that the parasitic resistances need not be considered as much, whereas the low resistance for improving the signal-quality required for the design of the lower inductor is not considered in the designing concept of the normal CMOS technique for the local wiring. That is, although the designing concept of the lower inductor is different from the designing concept of the local wiring in the normal CMOS technique, the signal amplitude of the signal transmitting in the lower inductor BL deteriorates due to the fact that the lower inductor is formed in wiring layer of the same layer as the local wiring.

In this regard, in the second feature point in the second embodiment, in order to realize a configuration in which a low-resistance lower inductor BL is disposed, a novel designing concept is adopted in which the lower inductor BL is formed in the same layer as a semi-global wiring or a global wiring having a low parasitic resistance, unlike a technique of using a normal CMOS technique in which the lower inductor BL is formed in the same layer as a local wiring having a large parasitic resistance. This designing concept can be realized because the first feature point of laminating the insulating substrate 1S on the semiconductor chip CHP2 is adopted so that the insulating substrate 1S formed with the upper inductor TL is disposed facing the lower inductor BL formed on the semiconductor chip CHP2. According to this designing concept, the thickness of the lower inductor BL can be increased, and consequently, the parasitic resistance of the lower inductor BL can be reduced. Thus, in the second feature point, since the parasitic resistance of the lower inductor BL can be reduced, deterioration of the signal amplitude of the signal transmitting in the lower inductor BL can be suppressed. That is, according to the second feature point, it is possible to improve the performance of the semiconductor device.

### Insulating Structure

Next, the details of the insulating structure will be described.

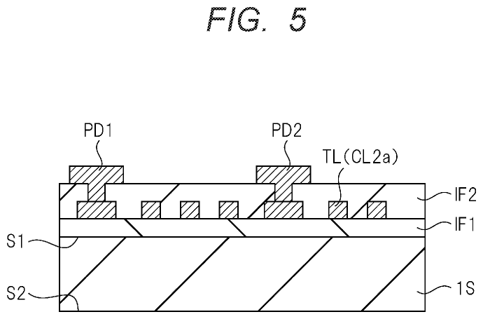

FIG. 5 is a cross-sectional view showing a detailed insulating structure.

In FIG. 5, the insulating substrate 1S has the first surface S1 and the second surface S2 opposite the first surface S1, and an insulating film IF1 is formed on the first surface S1. The insulating film IF1 is formed of, for example, an organic insulating film such as a polyimide resin film.

The upper inductor TL (coil CL2a) is formed on the insulating film IF1, and an insulating film IF2 is formed so as to cover the upper inductor TL. The upper inductor TL is formed of, for example, a copper film or an aluminum film, and the insulating film IF2 is formed of, for example, an organic insulating film such as a polyimide resin film.

The insulating film IF2 includes a plurality of openings, and a pad PD1 and a pad PD2 are formed on the insulating film IF2 so as to fill the openings. Each of the pad PD1 and the pad PD2 is formed of, for example, a copper film (Cu film) or a laminated film of Au/Ni/Cu.

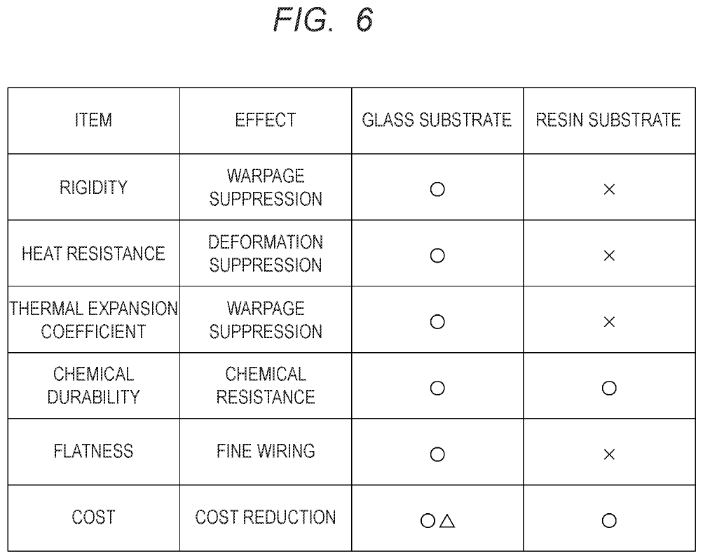

Here, the insulating substrate 1S is preferably made of a glass substrate. This is because, as shown in FIG. 6, the glass substrate has characteristics such as high rigidity, high heat resistance (thermal stability), thermal expansion coefficient, and high chemical durability compared to the resin substrate. In addition, the glass substrate is excellent in that it has high processing accuracy and high flatness, and thus can be stabilized at the time of resin sealing or substrate adsorption.

The insulating structure is configured as described above.

### Manufacturing Method of Insulating Structure

The manufacturing method of the insulating structure will be described.

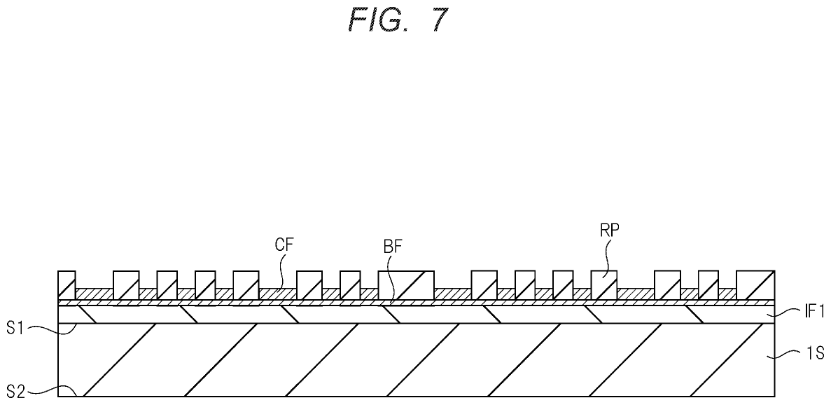

As shown in FIG. 7, for example, the insulating substrate 1S made of the glass substrate is prepared, and then the insulating film IF1 is formed on the first surface S1 of the insulating substrate 1S. The insulating film IF1 is formed of, for example, an organic insulating film such as a polyimide resin film, and can be formed by, for example, a coating method.

Next, a barrier metal film is formed on the insulating film IF1, and then a seed film is formed on the barrier metal film. As a result, a base film BF formed of a barrier metal film and a seed film is formed. At this time, the barrier metal film is formed of, for example, a chromium film, and can be formed by using, for example, a sputtering method. The seed film is formed of, for example, a copper film, and can be formed by using, for example, a sputtering method.

Subsequently, a resist pattern RP is formed on the base film BF by using a photolithography technique. Thereafter, a conductive film CF formed of, for example, a copper film is formed on the base film BF exposed from the resist pattern RP by using a plating method.

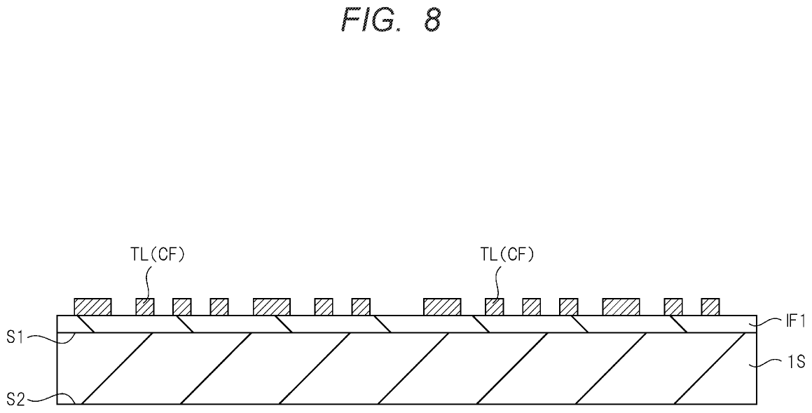

Next, as shown in FIG. 8, the resist pattern RP is removed by asking the resist pattern. Then, for example, the base film BF exposed from the conductive film CF is removed by using a wet etching technique. Note that after this state, the conductive film CF and the base film BF are integrally represented as the conductive film CF. Thus, the upper inductor TL formed of the conductive film CF can be formed.

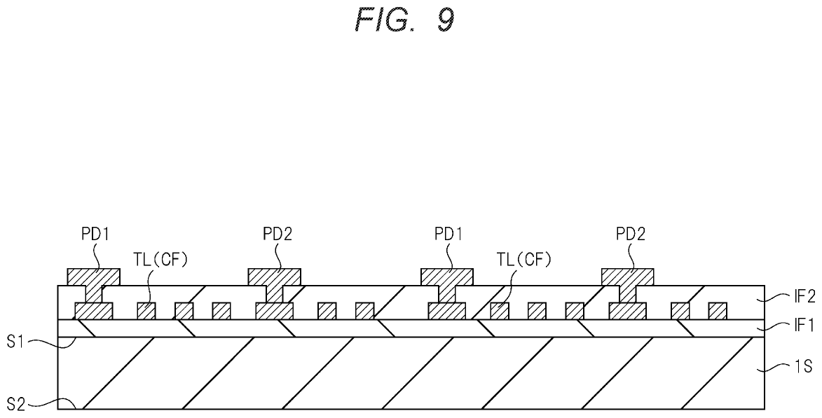

Thereafter, as shown in FIG. 9, the insulating film IF2 is formed on the insulating film IF1 on which the upper inductor TL is formed. The insulating film IF2 is formed of, for example, an organic insulating film such as a polyimide resin film, and can be formed by using, for example, a coating method.

Next, the insulating film IF2 is patterned using a photolithography technique to form openings. Subsequently, as in the case of forming the conductive film CF, a barrier metal film and a seed film are formed on the insulating film IF2. Thereafter, the conductive film formed of, for example, a copper film (Cu film) or a laminated film of Au/Ni/Cu is formed using a photolithography technique and a plating method. Thus, the pad PD1 and the pad PD2 electrically connected to the conductive film CF as shown in FIG. 9 can be formed.

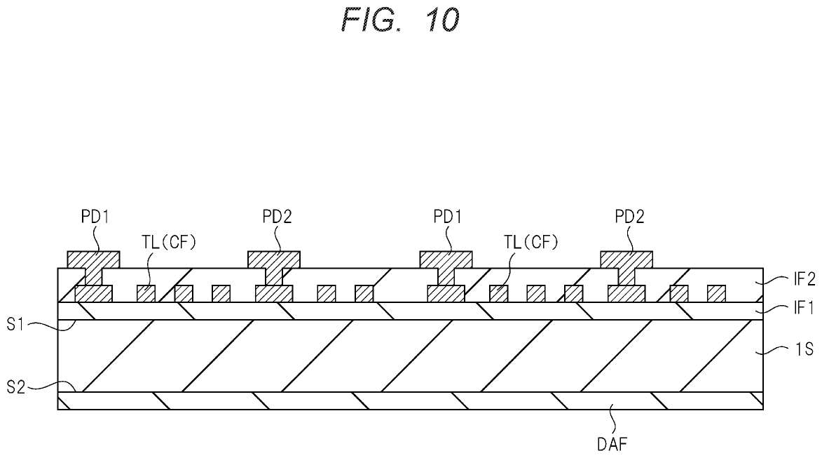

Subsequently, as shown in FIG. 10, the adhesive member DAF is attached to the second surface (back surface) S2 of the insulating substrate 1S. The adhesive member DAF is formed of, for example, a die attach film.

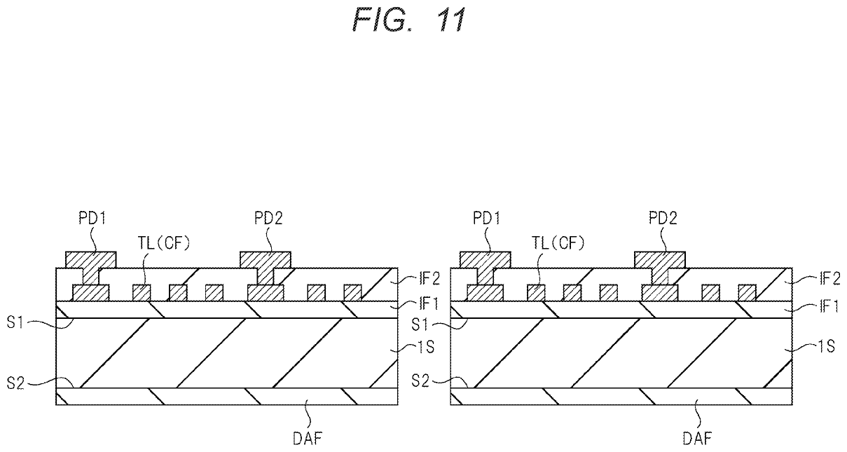

Then, as shown in FIG. 11, the insulating film IF2, the insulating film IF1, the insulating substrate 1S, and the adhesive member DAF are cut by the dicing step. Thus, the insulating structure can be manufactured.

### Three-Chip Configuration

In the semiconductor device in the above-described first embodiment, the two-chip configuration is employed. However, in the two-chip configuration, for example, the transformer TR1, the transmitting circuit TX1, and the receiving circuit RX2 need to be formed on one semiconductor chip resulting in complicating the manufacturing process of the semiconductor chip CHP1. Alternatively, in the two-chip configuration, for example, the transformer TR2, the drive circuit DR, the receiving circuit RX1, and the transmitting circuit TX2 need to be formed on one semiconductor chip resulting in complicating the manufacturing process of the semiconductor chip CHP2. As a consequence, the manufacturing costs of the semiconductor chip CHP1 and the semiconductor chip CHP2 may increase.

Therefore, it has been studied to realize the above-described semiconductor device not in the two-chip configuration but in the three-chip configuration. Hereinafter, a novel three-chip configuration will be described.

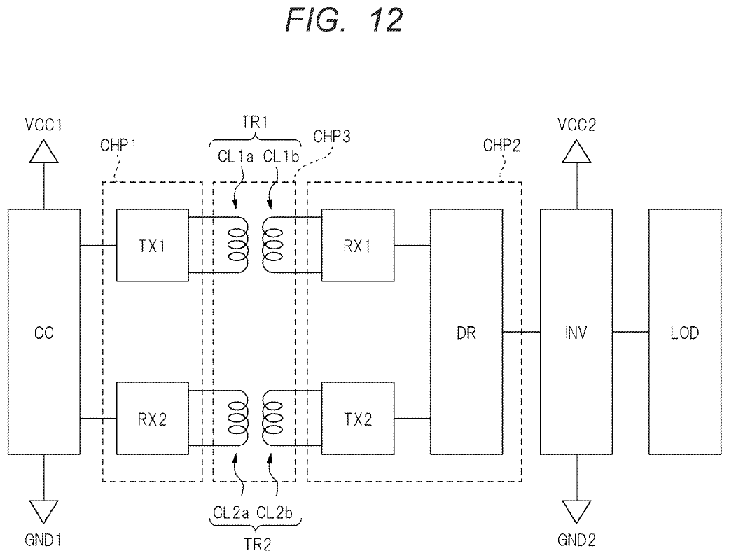

FIG. 12 is a diagram showing a three-chip configuration.

In FIG. 12, the transmitting circuit TX1 and the receiving circuit RX2 are formed in the semiconductor chip CHP1. In addition, the drive circuit DR, the receiving circuit RX1, and the transmitting circuit TX2 are formed in the semiconductor chip CHP2. On the other hand, the transformer TR1 and the transformer TR2 are formed in a semiconductor chip CHP3.

Thus, in the three-chip configuration, only the transformer TR1 and the transformer TR2 are formed in the semiconductor chip CHP3. That is, in the three-chip configuration, the semiconductor chip CHP3 can be used regardless of the configuration of the semiconductor chip CHP1 and the semiconductor chip CHP2. As a result, according to the three-chip configuration, the usable variation of the semiconductor chip CHP1 and the semiconductor chip CHP2 can be increased. In other words, the versatility of the semiconductor chip CHP3 in which the transformer TR1 and the transformer TR2 are formed can be improved. Further, since the semiconductor chip CHP3 in which the transformer TR1 and the transformer TR2 are formed does not include a transistor, the semiconductor chip CHP3 can be formed only by wiring process, and thus the manufacturing process can be simplified. Therefore, the three-chip configuration can reduce the manufacturing cost, and thus a highly competitive product can be manufactured.

However, in the above-described three-chip configuration, for example, focusing on the transformer TR2, the coil CL2a (upper inductor) and the coil CL2b (lower inductor) configuring the transformer TR2 are formed in the semiconductor chip CHP3. In this case, the breakdown voltage of the transformer TR2 is ensured by the thickness of the multilayer wiring layer (the thickness of the laminated insulating films) formed on the semiconductor chip CHP3.

However, when both the coil CL2a and the coil CL2b which form the transformer TR2 are formed in the multilayer wiring layer, the distance between the coil CL2a and the coil CL2b is at most about 4 μm. In this regard, when the distance between the coil CL2a and the coil CL2b is about 4 μm, it is difficult to ensure an enough breakdown voltage of about 5000V in terms of alternating current.

Therefore, in the following description, a modified example according to the first embodiment will be described, in which, in a three-chip configuration, the breakdown voltage between the coil CL2a and the coil CL2b (for example, the breakdown voltage 5000 V in terms of alternating current) is secured by using a new insulating substrate different from the semiconductor chip CHP3.

### First Modified Example of First Embodiment

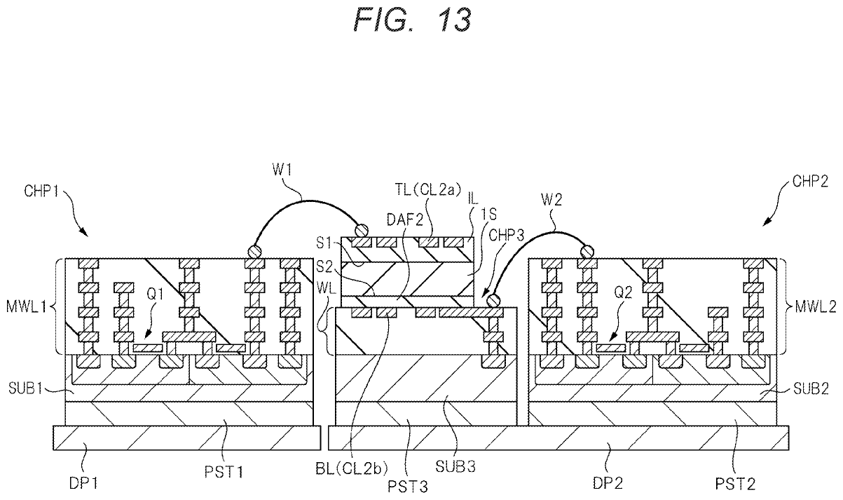

FIG. 13 is a cross-sectional view showing a schematic configuration of a semiconductor device according to the first modified example.

In FIG. 13, the semiconductor device includes the semiconductor chip CHP1, the semiconductor chip CHP2, and the semiconductor chip CHP3. That is, the semiconductor device in the first modified example has a three-chip configuration. As shown in FIG. 13, the semiconductor chip CHP1 is mounted, for example, on the die pad DP1 that is a chip mounting portion, via the conductive adhesive PST1. On the other hand, the semiconductor chip CHP2 is mounted, for example, on the die pad DP2 which is a chip mounting portion via, the conductive adhesive PST2. The semiconductor chip CHP3 is also mounted on the die pad DP2 via a conductive adhesive PST3.

Here, each of the die pad DP1 and the die pad DP2 is made of, for example, a copper material. Each of the conductive adhesive PST1, the conductive adhesive PST2, and the conductive adhesive PST3 is made of, for example, silver-paste or solder.

The transmitting circuit TX1 and the receiving circuit RX2 shown in FIG. 12 are formed in the semiconductor chip CHP1. On the other hand, in the semiconductor chip CHP2, the drive circuit DR, the receiving circuit RX1, and the transmitting circuit TX2 shown in FIG. 12 are formed.

Next, as shown in FIG. 13, the semiconductor chip CHP3 includes a semiconductor substrate SUB3 and the wiring layer WL formed on the semiconductor substrate SUB3. The lower inductor BL (coil CL2b), which is a component of the transformer, is formed in the uppermost layer of the wiring layer WL. In this case, in order to fix the potential of the semiconductor substrate SUB3, the lower inductor BL and the semiconductor substrate SUB3 are electrically connected to each other via the wiring and the diffusion layer. The lower inductor BL is electrically connected, for example, to wiring disposed in the multilayer wiring layer MWL2 of the semiconductor chip CHP2 via a bonding wire W2.

Subsequently, in the semiconductor chip CHP3, the insulating substrate 1S is disposed on the wiring layer WL in which the lower inductor BL is formed, via an adhesive member DAF2. Here, the adhesive member DAF2 is formed of, for example, a die attach film. The insulating substrate 1S is made of a glass substrate. On the insulating substrate 1S, the insulating layer IL and the upper inductor TL (coil CL2a) which is formed on the insulating layer IL and is a component of the transformer are formed. The upper inductor TL is electrically connected, for example, to wiring disposed in the multilayer wiring layer MWL1 of the semiconductor chip CHP1 via a bonding wire W1.

The thickness of the insulating substrate 1S is greater than the thickness of the wiring layer WL. Specifically, the thickness of the semiconductor substrate SUB3 is about 400 μm, the thickness of wiring layer WL is about several μm, and the thickness of the insulating substrate 1S is about 100 μm. As described above, the insulating substrate 1S having a thickness of about 100 μm is laminated on the semiconductor chip CHP3 having a thickness of about 400 μm.

The semiconductor device according to the first modified example includes the semiconductor chip CHP2 having a circuit (second circuit) applying the second potential to the lower inductor BL, and the semiconductor chip CHP3 in which the lower inductor BL is formed. Here, the lower inductor BL formed in the semiconductor chip CHP3 is electrically connected to the circuit (second circuit) formed in the semiconductor chip CHP2 via the bonding wire W2. That is, in plan view, the size of the semiconductor chip CHP3 is larger than the size of the insulating substrate 1S, and the semiconductor chip CHP3 is electrically connected to the semiconductor chip CHP2 via the bonding wire W2 in the non-mounting region of the semiconductor chip CHP3 on which the insulating substrate 1S is not mounted. Specifically, the lower inductor BL, the pad, and the wiring that electrically connects the lower inductor BL and the pad are formed in the uppermost layer of the wiring layer WL, and the insulating substrate 1S is disposed on the semiconductor chip CHP3 so that the pad is exposed from the insulating substrate 1S. Since the pad is formed so as not to overlap with the insulating substrate 1S, the pad electrically connected to the lower inductor BL can be electrically connected to the semiconductor chip CHP2 via the bonding wire W2.

In the semiconductor device of the first modified example configured as described above, as shown in FIG. 13, the insulating substrate 1S is disposed on the semiconductor chip CHP3 such that the insulating substrate 1S including the upper inductor TL is disposed to face the lower inductor BL formed in the semiconductor chip CHP3 along the thickness direction of the insulating substrate 1S.

Thus, according to the semiconductor device of the first modified example, the upper inductor TL and the lower inductor BL are magnetically coupled to form a transformer, and the breakdown voltage between the upper inductor TL and the lower inductor BL can be ensured by the thickness of the insulating substrate 1S.

In addition, in the semiconductor device of the first modified example, as shown in FIG. 13, the lower inductor BL formed in the semiconductor chip CHP3 is disposed, for example, in the uppermost wiring layer.

Thus, according to the semiconductor device of the first modified example, the thickness of the lower inductor BL can be increased. Therefore, in the lower inductor BL, since the parasitic resistance can be reduced, deterioration of the signal amplitude of the signal transmitting in the lower inductor BL can be suppressed.

### Second Modified Example of First Embodiment

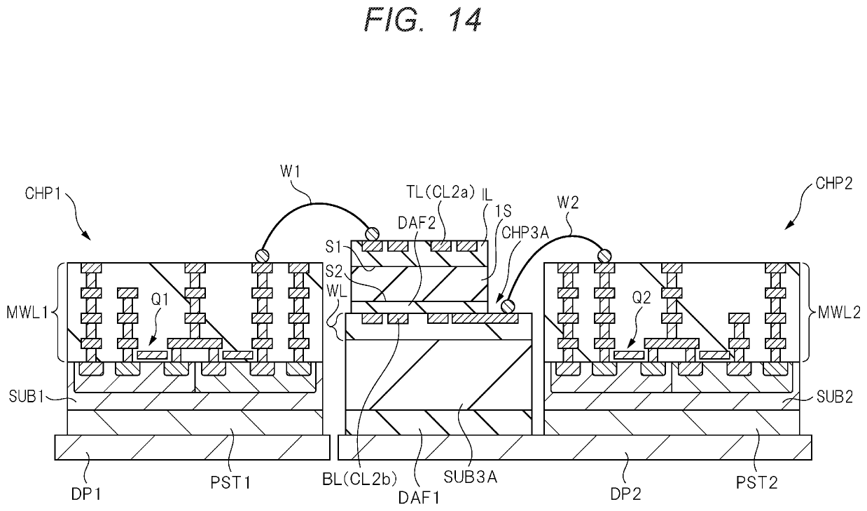

FIG. 14 is a cross-sectional view showing a schematic configuration of a semiconductor device according to the second modified example.

In FIG. 14, the semiconductor device includes the semiconductor chip CHP1, the semiconductor chip CHP2, and a chip CHP3A. That is, the semiconductor device in the second modified example has a three-chip configuration. As shown in FIG. 14, the semiconductor chip CHP1 is mounted, for example, on the die pad DP1 that is a chip mounting portion, via the conductive adhesive PST1. On the other hand, the semiconductor chip CHP2 is mounted, for example, on the die pad DP2 which is a chip mounting portion, via the conductive adhesive PST2. The chip CHP3A is also mounted on the die pad DP2 via an adhesive member DAFT.

Here, each of the die pad DP1 and the die pad DP2 is made of, for example, a copper material. Each of the conductive adhesive PST1 and the conductive adhesive PST2 is made of, for example, silver-paste or solder. The adhesive member DAFT is formed of, for example, a die attach film.

The transmitting circuit TX1 and the receiving circuit RX2 shown in FIG. 12 are formed in the semiconductor chip CHP1. On the other hand, in the semiconductor chip CHP2, the drive circuit DR, the receiving circuit RX1, and the transmitting circuit TX2 shown in FIG. 12 are formed.

Next, as shown in FIG. 14, the chip CHP3A includes an insulating substrate SUB3A made of, for example, glass substrate, and the wiring layer WL formed on the insulating substrate SUB3A. The lower inductor BL (coil CL2b), which is a component of the transformer, is formed in the uppermost layer of the wiring layer WL.

Here, the lower inductor BL is electrically connected to the wiring disposed in the multilayer wiring layer MWL2 of the semiconductor chip CHP2 via the bonding wire W2.

Subsequently, in the chip CHP3A, the insulating substrate 1S is laminated on the wiring layer WL in which the lower inductor BL is formed, via the adhesive member DAF2. Here, the adhesive member DAF2 is formed of, for example, a die attach film. The insulating substrate 1S is made of a glass substrate. On the insulating substrate 1S, the upper inductor TL (coil CL2a), which is a component of the transformer, is formed together with the insulating layer IL. The upper inductor TL is electrically connected to the wiring disposed in the multilayer wiring layer MWL1 of the semiconductor chip CHP1 via the bonding wire W1.

The thickness of the insulating substrate 1S is greater than the thickness of the wiring layer WL. Specifically, the thickness of the insulating substrate SUB3A is about 400 μm, the thickness of the wiring layer WL is about several μm, and the thickness of the insulating substrate 1S is about 100 μm. As described above, the insulating substrate 1S having a thickness of about 100 μm is laminated on the tip CHP3A having a thickness of about 400 μm.

The semiconductor device in the second modified example includes the semiconductor chip CHP2 including the circuit (second circuit) applying the second potential to the lower inductor BL and the chip CHP3A in which the lower inductor BL is formed. Here, the lower inductor BL formed in the chip CHP3A is electrically connected to the circuit (second circuit) formed in the semiconductor chip CHP2 via the bonding wire W2. That is, in plan view, the size of the chip CHP3A is larger than the size of the insulating substrate 1S, and the chip CHP3A is electrically connected to the semiconductor chip CHP2 via the bonding wire W2 in the non-mounting region of the chip CHP3A on which the insulating substrate 1S is not mounted.

In the semiconductor device configured as described above according to the second modified example, as shown in FIG. 14, the insulating substrate 1S is laminated on the chip CHP3A so that the insulating substrate 1S including the upper inductor TL faces the lower inductor BL formed in the chip CHP3A along the thickness direction of the insulating substrate 1S.

Thus, according to the semiconductor device in the second modified example, the upper inductor TL and the lower inductor BL are magnetically coupled to form the transformer, and the breakdown voltage between the upper inductor TL and the lower inductor BL can be ensured by the thickness of the insulating substrate 1S.

In addition, in the semiconductor device of the second modified example, as shown in FIG. 14, the lower inductor BL formed in the chip CHP3A is disposed, for example, in the uppermost wiring layer.

Thus, according to the semiconductor device of the second modified example, the thickness of the lower inductor BL can be increased. Therefore, in the lower inductor BL, since the parasitic resistance can be reduced, deterioration of the signal amplitude of the signal transmitting in the lower inductor BL can be suppressed.

Further, according to the semiconductor device of the second modified example, the chip CHP3A uses the insulating substrate SUB3A represented by a glass substrate instead of the semiconductor substrate. Thus, as can be seen from the comparison between FIG. 13 and FIG. 14, it is not necessary to provide a connecting structure fixing the potential of wiring including the lower inductor formed in the wiring layer WL formed on the insulating substrate SUB3 to the ground. That is, according to the second modified example, the device structure of the chip CHP3A can be simplified, and thus the manufacturing cost of the chip CHP3A can be reduced.

### Second Embodiment

### Configuration of Semiconductor Device

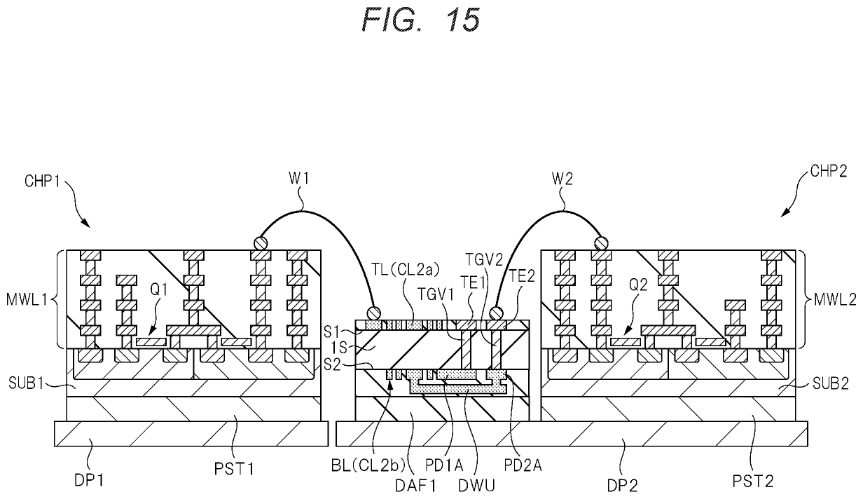

FIG. 15 is a cross-sectional view showing a schematic configuration of a semiconductor device in the second embodiment.

In FIG. 15, the semiconductor device includes the semiconductor chip CHP1, the semiconductor chip CHP2, and the insulating substrate 1S in which the transformer is formed. The semiconductor chip CHP1 is mounted, for example, on the die pad DP1 that is a chip mounting portion via the conductive adhesive PST1. On the other hand, the semiconductor chip CHP2 is mounted, for example, on the die pad DP2 which is a chip mounting portion via the conductive adhesive PST2. The insulating substrate 1S is mounted on the die pad DP2 via the adhesive member DAFT.

Here, each of the die pad DP1 and the die pad DP2 is made of, for example, a copper material. Each of the conductive adhesive PST1 and the conductive adhesive PST2 is made of, for example, silver-paste or solder. Further, the adhesive member DAFT is formed of, for example, a die attach film.

The transmitting circuit TX1 and the receiving circuit RX2 shown in FIG. 3 are formed in the semiconductor chip CHP1. As shown in FIG. 15, the semiconductor chip CHP1 includes the semiconductor substrate SUB1 and the multilayer wiring layer MWL1 formed on the semiconductor substrate SUB1. The plurality of transistors Q1 is formed on the semiconductor substrate SUB1, and the multilayer wiring layer MWL1 is formed over the semiconductor substrate SUB1 in which the plurality of transistors Q1 is formed. A wiring is formed in each layer of the multilayer wiring layer MWL1, and the wiring is electrically connected to the transistor Q1. The transistor Q1 and the wiring electrically connected to each other configure the transmitting circuit TX1 and the receiving circuit RX2.

Next, the drive circuit DR, the receiving circuit RX1, and the transmitting circuit TX2 shown in FIG. 3 are formed in the semiconductor chip CHP2. As shown in FIG. 15, the semiconductor chip CHP2 includes the semiconductor substrate SUB2 and the multilayer wiring layer MWL2 formed on the semiconductor substrate SUB2. The plurality of transistors Q2 is formed in the semiconductor substrate SUB2, and the multilayer wiring layer MWL2 is formed over the semiconductor substrate SUB2 in which the plurality of transistors Q2 is formed. A wiring is formed in each layer of the multilayer wiring layer MWL2, and the wiring is electrically connected to the transistor Q2. The transistor Q2 and the wiring electrically connected to each other configure the drive circuit DR, the receiving circuit RX1, and the transmitting circuit TX2.

Subsequently, as shown in FIG. 15, the transformer that performs contactless communication between different potentials is formed in the insulating substrate 1S. Specifically, the insulating substrate 1S has the first surface S1 and the second surface S2 located opposite the first surface S1, and the upper inductor TL is formed on the first surface S1, while the lower inductor BL is formed on the second surface S2. Further, the insulating substrate 1S is formed with a through-via TGV1 and a through-via TGV2 that penetrate through the insulating substrate 1S and are electrically connected to the lower inductor BL.

The upper inductor TL formed on the first surface S1 of the insulating substrate 1S is electrically connected to a circuit (first circuit) formed in the semiconductor chip CHP1 via the bonding wire W1. Further, the through-via TGV1 formed in the insulating substrate 1S is electrically connected to a connection terminal TE1 formed on the first surface S1 of the insulating substrate 1S, similarly, the through-via TGV2 formed in the insulating substrate 1S is electrically connected to a connection terminal TE2 formed on the first surface S1 of the insulating substrate 1S. Further, although not shown in FIG. 15, the connection terminal TE1 formed on the first surface S1 of the insulating substrate 1S is electrically connected to a circuit (second circuit) formed on the semiconductor chip CHP2 via the bonding wire. Further, as shown in FIG. 15, the connection terminal TE2 formed on the first surface S1 of the insulating substrate 1S is electrically connected to a circuit formed in the semiconductor chip CHP2 via the bonding wire W2. The lower inductor BL formed on the second surface S2 of the insulating substrate 1S is electrically connected to the circuit formed in the semiconductor chip CHP2 via the through-via TGV1(TGV2), the connection terminal TE1(TE2), and the bonding wire W2.

For example, in FIG. 15, the upper inductor TL is formed of a spiral inductor, and similarly, the lower inductor BL is formed of a spiral inductor. In this case, as shown in FIG. 15, the upper inductor TL is formed of a single layer, while the lower inductor BL is formed of at least two layers. That is, the lower inductor BL includes the first layer wiring formed on the second surface S2, the second layer wiring formed on the first layer wiring, and the conductive member that connects the first layer wiring and the second layer wiring.

The lower inductor BL includes a pad PD1A formed in one layer of the two layers, a pad PD2A formed in the one layer, and a lead wiring portion DWU formed in the one layer described above and in another one layer of the two layers and electrically connected to the pad PD2A. Here, there are a plurality of through-vias, and the plurality of through-vias includes the through-via TGV1 electrically connected to the pad PD1A and the through-via TGV2 electrically connected to the lead wiring portion DWU.

The semiconductor device in the second embodiment is configured as described above.

### Features of Semiconductor Device

In the semiconductor device of the second embodiment, as shown in FIG. 15, the upper inductor TL is formed on the first surface S1 of the insulating substrate 1S, and the lower inductor BL is formed on the second surface S2 of the insulating substrate 1S. As a result, the upper inductor TL and the lower inductor BL are disposed to face each other so as to sandwich the insulating substrate 1S in the thickness direction of the insulating substrate 1S. Consequently, according to the semiconductor device of the second embodiment, the breakdown voltage between the upper inductor TL and the lower inductor BL can be ensured by the thickness of the insulating substrate 1S while the upper inductor TL and the lower inductor BL are magnetically coupled to form the transformer. Thus, according to the second embodiment, the reliability of the semiconductor device can be improved.

In the semiconductor device of the second embodiment, as shown in FIG. 15, for example, the transformer is formed in the insulating substrate 1S different from the semiconductor chip CHP1 or the semiconductor chip CHP2 formed using the normal CMOS technique. Since no transistor is formed in the insulating substrate 1S, the transformer formed in the insulating substrate 1S can be formed based on a new designing concept suitable for forming the transformer without using the normal CMOS technique. Therefore, for example, the thickness of the upper inductor TL and the thickness of the lower inductor BL formed in the insulating substrate 1S can be increased. Consequently, since the parasitic resistance can be reduced in both the upper inductor TL and the lower inductor BL, it is possible to suppress deterioration of the signal amplitude of the signal transmitting in each of the upper inductor TL and the lower inductor BL. Thus, according to the second embodiment, the performance of the semiconductor device can be improved.

Further, in the semiconductor device of the second embodiment, as shown in FIG. 15, the lower inductor BL is formed on the second surface S2 of the insulating substrate 1S. In this regard, the lower inductor BL is configured to be electrically connected from the pad PD1A via the through-via TGV1 to the connection terminal TE1 on the first surface S1, and is configured to be electrically connected from the lead wiring portion DWU via the pad PD2A and the through-via TGV2 to the connection terminal TE2 on the first surface S1. Thus, according to the semiconductor device of the second embodiment, although the lower inductor BL is formed on the second surface S2 of the insulating substrate 1S, the connection terminal TE2 connected to the lower inductor BL can be connected to the circuit formed in the semiconductor chip CHP2 on the first surface S1 side. That is, according to the semiconductor device in the second embodiment, as shown in FIG. 15, even if the insulating substrate 1S is mounted on the die pad BL with the first surface CHP2 facing upward, not only the upper inductor TL formed on the first surface S1 and the circuit formed in the semiconductor chip CHP1 can be electrically connected to each other via the bonding wire W1, but also the lower inductor BL formed on the second surface S2 and the circuit formed in the semiconductor chip CHP2 can be electrically connected to each other via the bonding wire W2.

### Insulating Structure

Next, an insulating structure including a transformer will be described.

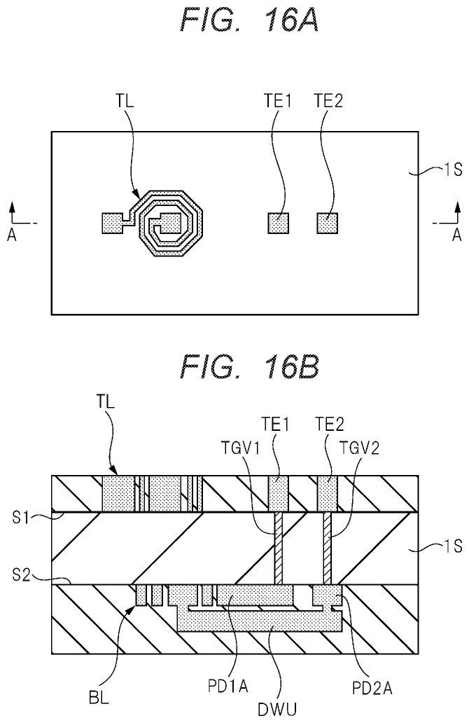

FIG. 16A is an upper surface diagram of an insulating structure having a transformer, and FIG. 16B is a cross-sectional view along A-A line of FIG. 16A.

In FIG. 16A, on the first surface S1 of the insulating substrate 1S, the upper inductor TL configured by a spiral inductor, the connection terminal TE1, and the connection terminal TE2 are disposed. Next, in FIG. 16B, the upper inductor TL formed on the first surface S1 of the insulating substrate 1S is formed as a single layer, while the lower inductor BL formed on the second surface S2 of the insulating substrate 1S is formed as two layers. The lower inductor BL includes the pad PD1A formed in one layer of the two layers, the pad PD2A formed in the one layer, and the lead wiring portion DWU formed in the one layer described above and in another one layer of the two layers and electrically connected to the pad PD2A. Here, there are a plurality of through-vias, and the plurality of through-vias includes the through-via TGV1 electrically connected to the pad PD1A and the through-via TGV2 electrically connected to the lead wiring portion DWU. The through-via TGV1 is electrically connected to the connection terminal TE1, while the through-via TGV2 is electrically connected to the connection terminal TE2. In this way, the upper inductor TL and the lower inductor BL configuring the transformer is disposed to face each other in the insulating substrate 1S, and the insulating distance between the upper inductor TL and the lower inductor BL is defined by the thickness of the insulating substrate 1S. The insulating structure is configured as described above.

### Manufacturing Method of Insulating Structure

Next, the manufacturing method of the insulating structure having a transformer will be described.

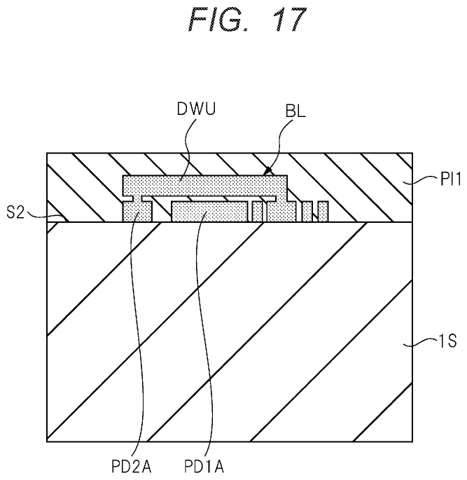

First, as shown in FIG. 17, the insulating substrate 1S made of, for example, the glass substrate having a thickness of 300 μm or more is prepared. Then, the lower inductor BL formed of two layers is formed on the second surface S2 of the insulating substrate 1S by using a sputtering method, a photolithography technique, a CVD method, or the like. The lower inductor BL includes the pad PD1A and the pad PD2A each formed in the first layer, and the lead wiring portion DWU formed in the second layer. Thereafter, an insulating film PI1 covering the lower inductor BL is formed on the second surface S2 of the insulating substrate 1S. The insulating film PI1 is formed of, for example, an organic insulating film such as a polyimide resin film, and can be formed by using, for example, a coating method.

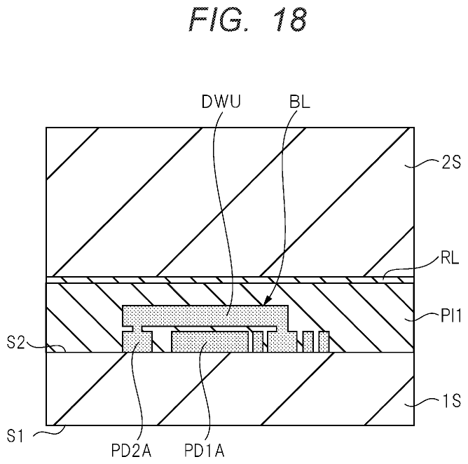

Next, as shown in FIG. 18, the insulating substrate 1S in which the lower inductor BL and the insulating film PI1 are formed is coupled to a supporting substrate 2S via a resin layer RL, and then the insulating substrate 1S is thinned. Specifically, the insulating substrate 1S is polished so that the thickness of the insulating substrate 1S becomes about 10 μm to 100 μm. Depending on the breakdown voltage of the transformer, the thickness of the insulating substrate 1S may be 100 μm or more.

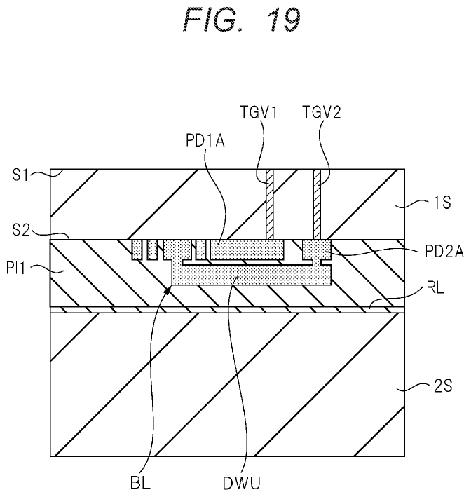

Subsequently, as shown in FIG. 19, a through-hole that penetrates through the insulating substrate 1S is formed by irradiating the first surface S1 of the insulating substrate 1S with a laser beam. Thereafter, the through-hole is filled with, for example, copper or the like to form the through-via TGV1 and the through-via TGV2.

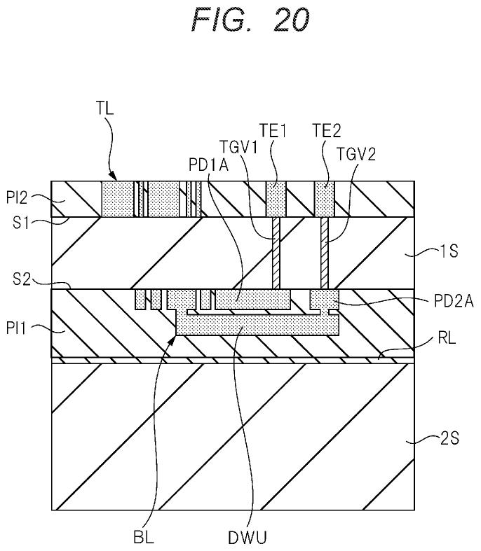

Thereafter, as shown in FIG. 20, the upper inductor TL, the connection terminal TE1, and the connection terminal TE2 are formed on the first surface S1 of the insulating substrate 1S using, for example, a sputtering method, a photolithography technique, a CVD method, and the like. Here, the connection terminal TE1 is formed so as to be electrically connected to the through-via TGV1, and the connection terminal TE2 is formed so as to be electrically connected to the through-via TGV2.

Then, an insulating film PI2 covering the upper inductor TL, the connection terminal TE1, and the connection terminal TE2 is formed on the first surface S1 of the insulating substrate 1S. The insulating film PI2 is formed of, for example, an organic insulating film such as a polyimide resin film, and can be formed by using, for example, a coating method. Thereafter, the insulating film PI2 is polished to expose the upper inductor TL, the connection terminal TE1, and the connection terminal TE2.

In this way, an insulating structure with a transformer can be formed. Further, by separating the insulating structure including the transformer from the supporting substrate 2S, the insulating structure including the transformer can be manufactured.

### First Modified Example of Second Embodiment

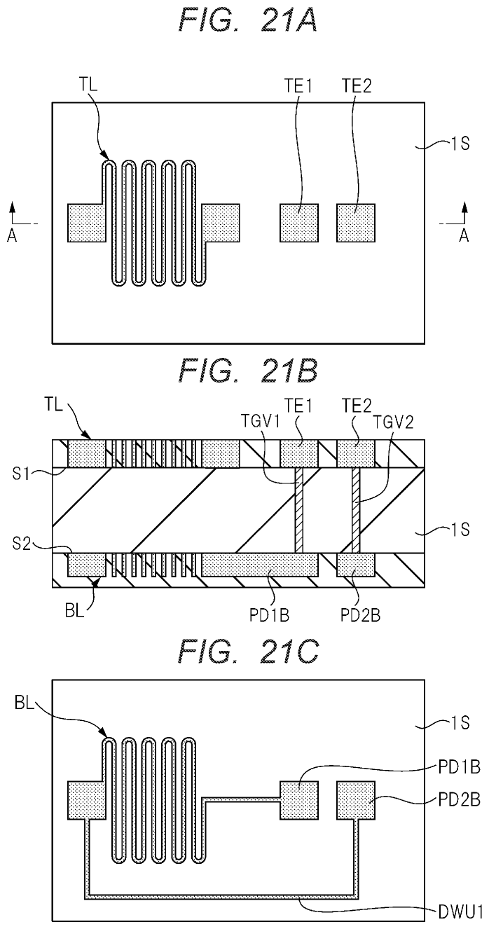

FIG. 21A is an upper surface diagram showing an insulating structure in the first modified example.

In FIG. 21A, the upper inductor TL formed of, for example, a meander inductor, the connection terminal TE1, and the connection terminal TE2 are formed on the insulating substrate 1S.

FIG. 21B is a cross-sectional view along A-A line in FIG. 21A.

As shown in FIG. 21B, the insulating substrate 1S has the first surface S1 and the second surface S2, and the upper inductor TL, the connection terminal TE1, and the connection terminal TE2 are formed on the first surface S1. On the other hand, the lower inductor BL is formed on the second surface S2. The lower inductor BL has a pad PD1B and a pad PD2B. The through-via TGV1 and the through-via TGV2 are formed so as to penetrate through the insulating substrate 1S, and the pad PD1B and the connection terminal TE1 are electrically connected to each other via the through-via TGV1. In addition, the pad PD2B and the connection terminal TE2 are electrically connected to each other via the through-via TGV2.

FIG. 21C is a bottom view showing an insulating structure in the first modified example.

In FIG. 21C, for example, the lower inductor BL configured by a meander inductor is formed on the insulating substrate 1S, the lower inductor BL has the pad PD1B and the pad PD2B, and the meander inductor configuring the lower inductor BL and the pad PD2B are connected to each other via a lead wiring portion DWU1.

As described above, in the insulating structures shown in FIGS. 21A to 21C, the upper inductor TL is configured by a meander inductor, and similarly, the lower inductor BL is also configured by a meander inductor. The upper inductor TL is formed of a single layer (first single layer), and the lower inductor BL is also formed of a single layer (second single layer). In this case, the lower inductor BL includes the pad PD1B formed in the second single layer, the pad PD2B formed in the second single layer, and the lead wiring portion DWU1 formed in the second single layer and electrically connected to the pad PD2B. A plurality of through-vias penetrating through the insulating substrate 1S is present, and the plurality of through-vias includes the through-via TGV1 electrically connected to the pad PD1B and the through-via TGV2 electrically connected to the pad PD2B.

As described above, in the insulating structure according to the first modified example, for example, as shown in FIG. 21C, the lower inductor BL is formed of a meander inductor. Consequently, the meander inductor and the pad PD2B can be connected by the lead wiring portion DWU1 in the second single layer. Thus, according to the first modified example, even if adopting the configuration in which the lower inductor BL formed on the second surface S2 is connected to the connection terminal TE1 and the connection terminal TE2 formed on the first surface S1, the lower inductor BL can be formed in a single layer instead of two layers by configuring the lower inductor BL by a meander inductor not a spiral inductor.

That is, when the lower inductor BL is formed of a spiral inductor, the lower inductor BL must necessarily be formed of two layers if the lower inductor BL formed on the second surface S2 and the connection terminal TE1 and the connection terminal TE2 formed on the first surface S1 are connected to each other. On the other hand, when the lower inductor BL is formed of a meander inductor, for example, the lower inductor BL can be formed of a single layer as a result of being able to be routed in a single layer instead of two layers as shown in FIG. 21C.

### Second Modified Example of Second Embodiment

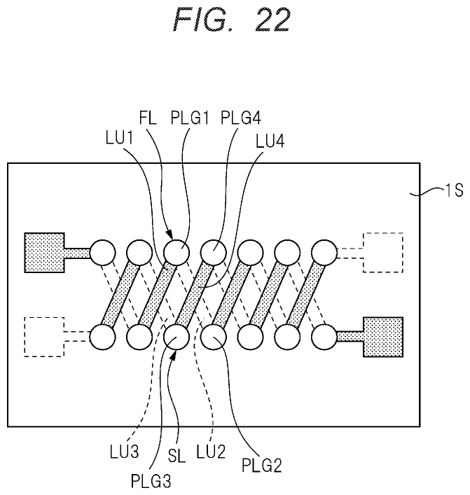

FIG. 22 is an upper surface diagram showing the insulating structure in the second modified example.

In FIG. 22, the insulating substrate 1S has the first surface (front surface) and the second surface (back surface) located opposite the first surface, and the first layer is formed on the first surface, while the second layer is formed on the second surface. Here, in FIG. 22, components formed in the first layer are indicated by solid lines, while components formed in the second layer are indicated by dotted lines.

As shown in FIG. 22, a first inductor FL and a second inductor SL are formed in the insulating substrate 1S. In this case, as shown in FIG. 22, the first inductor FL has a first wiring portion LU1 formed in the first layer, a first plug PLG1 connected to the first wiring portion LU1, a second wiring portion LU2 connected to the first plug PLG1 and formed in the second layer, and a second plug PLG2 connected to the second wiring portion LU2.

On the other hand, as shown in FIG. 22, the second inductor SL has a third wiring portion LU3 formed in the second layer, a third plug PLG3 connected to the third wiring portion LU3, a fourth wiring portion LU4 connected to the third plug PLG3 and formed in the first layer, and a fourth plug PLG4 connected to the fourth wiring portion LU4.

Here, in plan view, the first wiring portion LU1 and the third wiring portion LU3 intersect with each other, and in plan view, the second wiring portion LU2 and the fourth wiring portion LU4 intersect with each other.

Thus, according to the second modified example, the first inductor FL and the second inductor SL, which are components of the transformer that performs contactless communication between different potentials, are formed so as to be magnetically coupled. According to the second modified example, each of the first inductor FL and the second inductor SL can be configured by the first layer (single layer) formed on the first surface of the insulating substrate 1S and the second layer (single layer) formed on the second surface of the insulating substrate 1S.

The invention made by the present inventor has been described above in detail based on the embodiment, but the present invention is not limited to the embodiment described above, and it is needless to say that various modifications can be made without departing from the gist thereof.

What is claimed is:

1. A semiconductor device comprising:
an insulating substrate; and
a first inductor formed on the insulating substrate, the first inductor being a component of a transformer performing contactless communication between different potentials,
wherein the first inductor is configured to be applied with a first potential, and
wherein the first inductor is formed so that the first inductor can be magnetically coupled with a second inductor configured to be applied with a second potential different from the first potential.

2. The semiconductor device according to claim 1, comprising:
a second chip including the second inductor,
wherein the insulating substrate has a first surface and a second surface located opposite the first surface,
wherein the first inductor is formed in an insulating layer formed on the first surface, and
wherein the insulating substrate is disposed on the second chip via an adhesive member such that the second inductor faces the second surface.

3. The semiconductor device according to claim 2,
wherein the second chip includes:
a transistor formed on a semiconductor substrate; and
a multilayer wiring layer formed over the transistor,
wherein the second inductor is formed in the multilayer wiring layer.

4. The semiconductor device according to claim 3,
wherein the second inductor is formed in an uppermost layer of the multilayer wiring layer.

5. The semiconductor device according to claim 3,
wherein a thickness of the insulating substrate is greater than a thickness of the multilayer wiring layer.

6. The semiconductor device according to claim 2, comprising:
a first chip including a first circuit applying the first potential to the first inductor,
wherein the first inductor formed on the insulating substrate is electrically connected to the first circuit formed in the first chip via a first conductive member.

7. The semiconductor device according to claim 6,
wherein the second chip includes a second circuit applying the second potential to the second inductor.

8. The semiconductor device according to claim 1, comprising:
a second chip including a second circuit applying the second potential to the second inductor; and
a third chip in which the second inductor is formed,
wherein the second inductor is electrically connected to the second circuit via a second conductive member.

9. The semiconductor device according to claim 8,
wherein in plan view, a size of the third chip is larger than a size of the insulating substrate,
wherein the insulating substrate is formed on the third chip, and
wherein a part of the third chip exposed from the insulating substrate is electrically connected to the second chip via the second conductive member.

10. The semiconductor device according to claim 1,
wherein the insulating substrate is a glass substrate.

11. The semiconductor device according to claim 1,
wherein the insulating substrate has a first surface and a second surface located opposite the first surface,
wherein the first inductor is formed in an insulating layer formed on the first surface,
wherein the second inductor is formed on the second surface, and
wherein at least one through-via penetrating through the insulating substrate and electrically connected to the second inductor is formed in the insulating substrate.

12. The semiconductor device according to claim 11, comprising:
a first chip including a first circuit applying the first potential to the first inductor; and
a second chip including a second circuit applying the second potential to the second inductor,
wherein the first inductor formed on the first surface of the insulating substrate is electrically connected to the first circuit formed in the first chip via a first conductive member,
wherein the at least one through-via formed in the insulating substrate is electrically connected to a connection terminal formed on the first surface of the insulating substrate,
wherein the connection terminal formed on the first surface of the insulating substrate is electrically connected to the second circuit formed in the second chip via a second conductive member, and
wherein the second inductor formed on the second surface of the insulating substrate is electrically connected to the second circuit formed in the second chip via the at least one through-via, the connection terminal and the second conductive member.

13. The semiconductor device according to claim 11,
wherein the first inductor is configured by a spiral inductor,
wherein the second inductor is configured by a spiral inductor,
wherein the first inductor is formed of a single layer,
wherein the second inductor is formed of two layers,
wherein the second inductor includes:
a first pad formed in one layer of the two layers;
a second pad formed in the one layer of the two layers; and
a lead wiring portion formed in the one layer and in an another layer of the two layers and electrically connected to the second pad,
wherein the at least one through-via comprises a plurality of through-vias,
wherein the plurality of through-vias includes:
a first through-via electrically connected to the first pad; and
a second through-via electrically connected to the lead wiring portion.

14. The semiconductor device according to claim 11,
wherein the first inductor is configured by a meander inductor,
wherein the second inductor is configured by a meander inductor,
wherein the first inductor is formed of a first single layer,
wherein the second inductor is formed of a second single layer,
wherein the second inductor includes:
a first pad formed in the second single layer;
a second pad formed in the second single layer; and
a lead wiring portion formed in the second single layer and electrically connected to the second pad,
wherein the at least one through-via comprises a plurality of through-vias,
wherein the plurality of through-vias includes:
a first through-via electrically connected to the first pad; and
a second through-via electrically connected to the second pad.

15. The semiconductor device according to claim 1,
wherein the insulating substrate has a first surface and a second surface located opposite the first surface,
wherein a first layer is formed on the first surface,
wherein a second layer is formed on the second surface,
wherein the first inductor includes:
a first wiring portion formed in the first layer;
a first plug connected to the first wiring portion;
a second wiring portion formed in the second layer and connected to the first plug; and
a second plug connected to the second wiring portion,
wherein the second inductor includes:
a third wiring portion formed in the second layer;
a third plug connected to the third wiring portion;
a fourth wiring portion formed in the first layer and connected to the third plug; and
a fourth plug connected to the fourth wiring portion,
wherein in plan view, the first wiring portion and the third wiring portion intersect with each other, and
wherein in plan view, the second wiring portion and the fourth wiring portion intersect with each other.
